(19) United States
(12) Patent Application Publication
(10) Pub. No.: US 2008/0157405 A1
(43) Pub. Date: Jul. 3, 2008

(54) CHIP STACK WITH PRECISION ALIGNMENT, HIGH YIELD ASSEMBLY AND THERMAL CONDUCTIVITY

(75) Inventor: John U. Knickerbocker, Monroe, NY (US)

Correspondence Address: CANTOR COLBURN LLP-IBM YORKTOWN, 20 Church Street, 22nd Floor, Hartford, CT, 06103, US

(73) Assignee: INTERNATIONAL BUSINESS MACHINES CORPORATION, Armonk, NY (US)

(21) Appl. No.: 11/619,265

(22) Filed: Jan. 3, 2007

(51) Int. Cl. H01L 23/544; H01L 21/50

(52) U.S. Cl. 257/797; 438/401; 438/109; 257/E23.179; 257/E21.499

(57) ABSTRACT

A method for fabricating a device adapted for precision aligning integrated circuits having small-scale architecture in a stack, the method includes obtaining dimensions of the integrated circuits; fabricating a precision guide using the dimensions; and fabricating alignment fiducials into at least one of the precision guide and a carrier wafer. A method for placing integrated circuits having small-scale architecture into a stack, the method includes selecting a device adapted for precision aligning the integrated circuits into the stack and precision aligning the integrated circuits into the stack.

IBM® is a registered trademark of International Business Machines Corporation, Armonk, N.Y., U.S.A. Other names used herein may be registered trademarks, trademarks or product names of International Business Machines Corporation or other companies.

### BACKGROUND OF THE INVENTION

1. Field of the Invention

This invention relates to interconnecting integrated circuits.

2. Description of the Related Art

A miniaturized electronic circuit may be manufactured into the surface of a semiconductor substrate. The miniaturized electronic circuit is referred to as an integrated circuit. The integrated circuits may be stacked vertically in order to save space.

Problems connecting the integrated circuits together may arise when stacking the integrated circuits. Further, the magnitude of the problems increases as the density of the electronic circuitry and associated input and output connections increases. Integrated circuits may be manufactured with micro-scale and even nano-scale dimensions.

Connections between the integrated circuits may be dual purpose. One purpose is for electrical conduction. Another purpose is for thermal conduction. Additional connections may be provided for electrical conduction and thermal conduction enhancement as the density of the electronic circuitry increases. Bonding pad sizes and distance between stacked integrated circuits may be designed to support high thermal conduction. The bonding pad sizes may be designed specifically for at least one of signal, power, ground, and thermal conduction.

Alignment of the integrated circuits is crucial for the connections to be made properly. If alignment of the integrated circuits in a stack is not precise, then the connections may be improperly made. Improper alignment may result in low manufacturing yield of integrated circuit stacks.

What are needed are methods and features to achieve precision alignment of a stack of integrated circuits for bonding the integrated circuits together.

### SUMMARY OF THE INVENTION

The shortcomings of the prior art are overcome and additional advantages are provided through a method for fabricating a device adapted for precision aligning integrated circuits having small-scale architecture in a stack, the method includes obtaining dimensions of the integrated circuits; fabricating a precision guide using the dimensions; and fabricating alignment fiducials into at least one of the precision guide and a carrier wafer.

Also disclosed is a method for placing integrated circuits having small-scale architecture into a stack, the method includes selecting a device adapted for precision aligning the integrated circuits into the stack and precision aligning the integrated circuits into the stack.

Further disclosed is a device adapted for stacking a plurality of integrated circuits, the device includes at least one alignment feature adapted for precision aligning each integrated circuit having a small-scale architecture, wherein the alignment features include a precision guide including a loading edge and at least one cavity, each cavity having at least one precision edge; and alignment fiducials including at least one of etched features on a semiconductor substrate and alignment pins.

System corresponding to the above-summarized methods are also described and claimed herein.

Additional features and advantages are realized through the techniques of the present invention. Other embodiments and aspects of the invention are described in detail herein and are considered a part of the claimed invention. For a better understanding of the invention with advantages and features, refer to the description and to the drawings.

### TECHNICAL EFFECTS

As a result of the summarized invention, technically we have achieved a solution with a device adapted for stacking a plurality of integrated circuits, the device includes at least one alignment feature adapted for precision aligning each integrated circuit having a small-scale architecture, wherein the alignment features include a precision guide including a loading edge and at least one cavity, each cavity having at least one precision edge; and alignment fiducials including at least one of etched features on a semiconductor substrate and alignment pins.

### BRIEF DESCRIPTION OF THE DRAWINGS

The subject matter which is regarded as the invention is particularly pointed out and distinctly claimed in the claims at the conclusion of the specification. The foregoing and other objects, features, and advantages of the invention are apparent from the following detailed description taken in conjunction with the accompanying drawings in which:

FIG. 1 illustrates a plurality of integrated circuits before alignment;

FIG. 2 illustrates a side view of one example of a precision guide;

FIG. 3 illustrates aspects of alignment features used to precision align the plurality of stacks of integrated circuits onto a carrier wafer;

FIG. 4 illustrates one example of stacking the plurality of integrated circuits with the alignment features providing precision alignment;

FIG. 5 illustrates one example of integrated circuit stacks after bonding;

FIG. 6 presents one exemplary method for fabricating alignment features; and

FIG. 7 presents one exemplary method for precision aligning the integrated circuits.

The detailed description explains the preferred embodiments of the invention, together with advantages and features, by way of example with reference to the drawings.

### DETAILED DESCRIPTION OF THE INVENTION

The teachings herein provide for methods and alignment features to precision align a stack of integrated circuits for bonding. The integrated circuits may include small-scale architecture. The alignment features assure precision alignment. The alignment features include at least one cavity. The cavity holds the stack of integrated circuits in a precision alignment. Once aligned, the stack of integrated circuits may be bonded by a variety of techniques. Additionally, using the alignment features described herein, the cavity may be precision aligned over an integrated circuit on a carrier wafer. The cavity may hold the stack of integrated circuits in precision alignment over the integrated circuit in the carrier wafer. As above, the stack of integrated circuits may be bonded by the variety of techniques. The teachings provide for, among other things, a plurality of cavities to precisely align a plurality of stacks of integrated circuits. The plurality of cavities may also be precision aligned over a plurality of integrated circuits in the carrier wafer. Before the methods and alignment features are described in detail certain definitions are provided.

The term “integrated circuit” relates to structures such as electrical circuits that are fabricated into a semiconductor material. In addition to the electrical circuits, the term “integrated circuit” includes optical devices fabricated at least one of into and on the semiconductor material. The optical devices may include, for example, optical lenses such as an array of micro-lenses, photo-detectors, and vertical cavity surface emitting lasers (VCSEL). The array of micro-lenses may be bonded to the semiconductor material. The term “small-scale architecture” relates to integrated circuits with dimensions that are measured in at least one of micrometers and nanometers. The term “carrier wafer” relates to a monolithic piece of semiconductor. Typically, the carrier wafer contains a plurality of integrated circuits. In general, the integrated circuits are not electrically connected. Further along in a fabricating process, the integrated circuits are typically separated from each other. The term “bonding” relates to forming electrical, thermal, and other connections. The term “bonding pad” relates to a structure where at least one of electrical conduction, thermal conduction, and other connections are made. The term “precision” relates to an amount of tolerance necessary to align the stack of integrated circuits for bonding. The amount of tolerance takes into account that adjustment of alignment may be accommodated by a surface tension of a soldering medium. The term “semiconductor substrate” relates to a material that may be etched and thinned. The material is used to fabricate the alignment features. The alignment features include the cavity discussed above. The term “stack structure” relates to a construction of the integrated circuits bonded together in a stack.

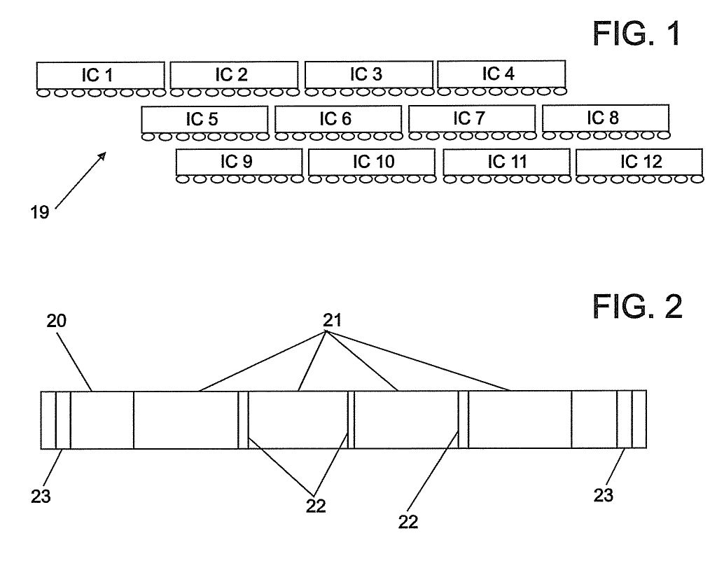

FIG. 1 illustrates a plurality of integrated circuits (IC) 19. The plurality of integrated circuits 19 includes twelve integrated circuits numbered consecutively from 1 to 12. The plurality of integrated circuits 19 illustrated in FIG. 1 is not aligned for bonding.

FIG. 2 illustrates a side view of one example of a precision guide 20. The precision guide 20 includes a plurality of cavities 21. Each of the cavities 21 is formed from at least one precision edge 22. The precision edge 22 provides for precision alignment of the integrated circuits 19. The precision guide 20 holds at least two stacked integrated circuits 19 in precision alignment for bonding. The precision guide 20 may also include alignment fiducials 23. The alignment fiducials 23 provide for precision alignment of the cavities 21 over the integrated circuits 19 in the carrier wafer. The alignment fiducials 23 are typically mechanical surface interlocks.

The precision guide 20 may be fabricated from a semiconductor substrate. Typically, the cavities 21 with the precision edges 22 are at least one of etched and thinned. The etching is typically performed with a photolithography process. The thinning may typically be performed by a mechanical grinding process.

The alignment fiducials 23 may be at least one of etched features and alignment pins. The etched features may be at least one of a raised and indented surface. The etched features interlock with features on the carrier wafer. For example, a raised surface feature on the precision guide 20 may interlock with a similar indented feature on the carrier wafer.

The precision guide 20 may also include a loading edge. The loading edge may at least partially surround the cavity 21. The purpose of the loading edge is to aid in stacking the integrated circuits 19 into the cavity 21.

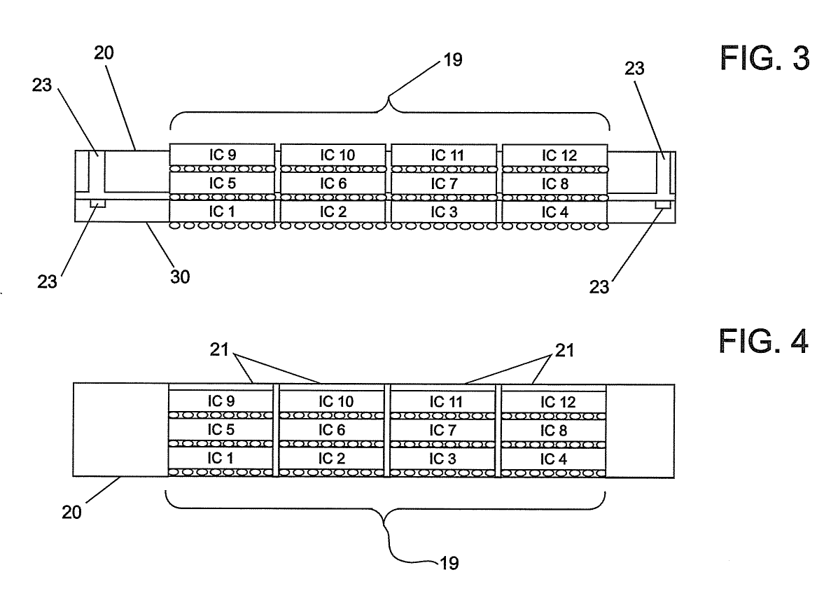

FIG. 3 illustrates one example of the precision guide 20 aligned atop a carrier wafer 30. The alignment fiducials 23 of the precision guide 20 are precision aligned with the alignment fiducials 23 of the carrier wafer 30. The plurality of integrated circuits 19 are precision aligned in stacks for bonding.

FIG. 4 illustrates using the precision guide 20 to precision align the plurality of integrated circuits 19 into stacks for bonding. In this example, groups of three integrated circuits 19 are stacked into the cavities 21. The carrier wafer 30 is not used in this example.

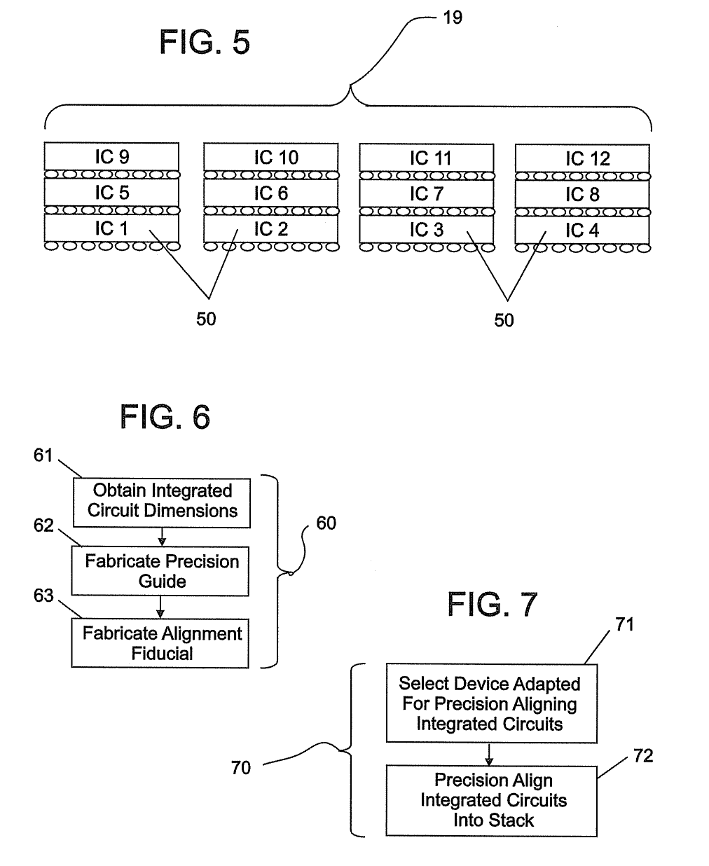

FIG. 5 illustrates one example of integrated circuit stacks 50 as a final product. The integrated circuit stacks 50 were formed by bonding stacks of integrated circuits 19. Typically, the integrated circuit stack 50 is separate from other integrated circuit stacks 50. However, other configurations of the integrated circuit stacks 50 may be provided.

The carrier wafer 30 typically contains a plurality of the integrated circuits 19. If the integrated circuit stacks 50 are fabricated with the carrier wafer 30 (as in FIG. 3), then the integrated circuit stacks 50 are usually separated from each other. Typically, the integrated circuit stacks 50 are separated by wafer dicing.

Several options exist for using the precision guides 20 and alignment fiducials 23. One option calls for stacking at least two of the precision guides 20 using the alignment fiducials 23. Another option calls for stacking at least two precision guides 20 atop the carrier wafer 30 using the alignment fiducials 23.

The precision guides 20 may be reused after cleaning.

Several options exist for bonding the integrated circuits 19 into integrated circuit stacks 50. Bonding of the integrated circuits 19 may be with at least one of solder to pad, solder to solder, copper to copper, solder reflow, pressure assisted join reflow, fusion, and copper to copper pressure and temperature bonding as well as other suitable techniques. Additionally, controlled flux ambient atmosphere and applied force may be used for joining to flat features such as bonding pads with oxide penetrating features. These bonding techniques may be compatible with volume production processes such as a belt reflow furnace process and a wafer stack bonding process. Bonding may benefit from immersion Au (gold) deposited on solder to permit wetting without use of fluxes.

Temperature, ambient environment, and force used in the bonding techniques are dependent upon interconnection metallurgies and stack structures used for the integrated circuit stacks 50. One embodiment of the bonding techniques includes use of a temperature of 250° C., CuSn solder micro-bumps of approximately 2 to 10 microns in height, applied force of approximately 0 to 400 psi, and a thickness of approximately 10 to 150 microns for each carrier wafer in the integrated circuits 19. For copper-to-copper bonding, one embodiment includes a temperature of approximately 350° C., applied force of approximately 60-400 psi, and an ambient environment of reduced oxygen. The ambient environment of reduced oxygen may include an inert atmosphere such as nitrogen. For AuSn and AuIn bonding, the ambient environment may be at least one of air or the inert atmosphere.

Spacing between the integrated circuits 19 may be regulated by the use of stops. The stops may be at least one of adhesive and mechanical. Additionally, underfill may be used between the integrated circuits 19. The underfill may be used for at least one of thermal conduction, mechanical packaging, mechanical handling, and corrosion protection. Exemplary embodiments of the underfill include a polymer and a filled polymer adhesive.

FIG. 6 presents one exemplary method 60 for fabricating the alignment features used to precision align the integrated circuits 19. A first step 61 calls for obtaining dimensions of the integrated circuits 19. A second step 62 calls for fabricating the precision guide 20. Fabricating the precision guide 20 includes fabricating at least one cavity 21 using the dimensions. Fabricating the cavity 21 may include fabricating at least one precision edge 22. A third step 63 calls for fabricating the alignment fiducials 23. The alignment fiducials 23 may be fabricated into at least one of the precision guide 20 and the carrier wafer 30.

FIG. 7 presents one exemplary method 70 of precision aligning the integrated circuits 19 for fabricating the integrated circuit stack 50. A first step 71 calls for selecting a device adapted for precision aligning the integrated circuits 19. The device typically includes alignment features. The alignment features assure precision alignment. The alignment features may include at least one of the precision guide 20 and the alignment fiducials 23. A second step 72 calls for precision aligning the integrated circuits 19 into stacks. The second step 72 may include bonding the stacks of the integrated circuits 19 to produce the integrated circuit stacks 50. The second step 72 may also include regulating the distance between the integrated circuits 19.

The flow diagrams depicted herein are just examples. There may be many variations to these diagrams or the steps (or operations) described therein without departing from the spirit of the invention. For instance, the steps may be performed in a differing order, or steps may be added, deleted or modified. All of these variations are considered a part of the claimed invention.

While the preferred embodiment to the invention has been described, it will be understood that those skilled in the art, both now and in the future, may make various improvements and enhancements which fall within the scope of the claims which follow. These claims should be construed to maintain the proper protection for the invention first described.

What is claimed is:

1. A method for fabricating a device adapted for precision aligning integrated circuits having small-scale architecture in a stack, the method comprising:
obtaining dimensions of the integrated circuits;
fabricating a precision guide using the dimensions; and
fabricating alignment fiducials into at least one of the precision guide and a carrier wafer.

2. The method as in claim 1 wherein, fabricating the precision guide comprises at least one of etching and thinning a semiconductor substrate.

3. The method as in claim 2 wherein, at least one of etching and thinning comprises forming a cavity with at least one precision edge.

4. The method as in claim 1 wherein, fabricating a precision guide comprises fabricating a loading edge.

5. The method as in claim 1 wherein, fabricating alignment fiducials comprises at least one of etching a semiconductor substrate and installing alignment pins.

6. A method for placing integrated circuits having small-scale architecture into a stack, the method comprising:
selecting a device adapted for precision aligning the integrated circuits into the stack and
precision aligning the integrated circuits into the stack.

7. The method as in claim 6, wherein precision aligning comprises aligning the integrated circuits with at least one of a precision guide and alignment fiducials.

8. The method as in claim 6, further comprising regulating the distance between the integrated circuits in the stack.

9. The method as in claim 8, wherein regulating the distance comprises installing at least one of adhesive and mechanical stops.

10. The method as in claim 6, further comprising bonding the integrated circuits.

11. The method as in claim 10, further comprising bonding with at least one of temperature, ambient environment, and applied force.

12. The method as in claim 10, wherein bonding comprises at least one of solder to pad, solder to solder, copper to copper, solder reflow, pressure assisted join reflow, fusion, and copper to copper pressure and temperature bonding.

13. The method as in claim 11, further comprising immersion gold deposited on the solder.

14. A device adapted for stacking a plurality of integrated circuits, the device comprising: at least one alignment feature adapted for precision aligning each integrated circuit having a small-scale architecture, wherein the alignment features comprise a precision guide comprising a loading edge and at least one cavity, each cavity comprising at least one precision edge; and alignment fiducials comprising at least one of etched features on a semiconductor substrate and alignment pins.
